(19) United States
(12) Patent Application Publication
(10) Pub. No.: US 2009/0324847 A1
(43) Pub. Date: Dec. 31, 2009

(54) Method of avoiding a parasitic plasma in a plasma source gas supply conduit

(75) Inventors: Soo Young Choi, Fremont, CA (US); John M. White, Hayward, CA (US)

Correspondence Address: SHIRLEY L. CHURCH, ESQ., P.O. BOX 81146, SAN DIEGO, CA, 92138, US

(73) Assignee: Applied Materials, Inc., Santa Clara, CA (US)

(21) Appl. No.: 12/583,814

(22) Filed: Aug. 25, 2009

Related U.S. Application Data
(63) Continuation of application No. 11/430,759, filed on May 9, 2006.

(51) Int. Cl. C23C 16/50

(52) U.S. Cl. 427/561

(57) ABSTRACT

It has been discovered that a parasitic plasma problem which has existed with respect to incoming plasma source gases present in a source gas feed line to a plasma processing chamber can be avoided. The stability of a parasitic plasma is avoided by installing an RF resistor conduit in the source gas feed line and increasing the pressure in the RF resistor conduit through which the plasma source gases flow. Use of a variable surface restrictor in the RF resistor conduit or between the RF resistor conduit and the plasma processing chamber enables not only avoidance of the formation of a parasitic plasma in incoming plasma source gases, but also easier cleaning of the processing chamber plasma generation system when a remotely generated plasma is used for such cleaning.

This application is a continuation application of U.S. application Ser. No. 11/430,759, filed May 9, 2006, and entitled: “Apparatus and Method for Avoidance of Parasitic Plasma in Plasma Source Gas Supply Conduits,” which is currently pending.

### BACKGROUND OF THE INVENTION

1. Field of the Invention

The invention generally relates to a method and apparatus useful in preventing the formation of a stable plasma in plasma source gas supply conduits.

2. Brief Description of the Background Art

The presence of information in this section is not an admission that such information is prior art with respect to the invention described and claimed herein.

Current interest in thin film transistor (TFT) arrays is particularly high because these devices are used in liquid crystal active matrix displays (LCDs) of the kind often employed for computer and television flat panels. The liquid crystal active matrix displays may also contain light-emitting diodes (LEDs) for back lighting. As an alternative to LCD displays, organic light-emitting diodes (OLEDs) have also been used for active matrix displays, and these organic light-emitting diodes require TFTs for addressing the activity of the displays.

The thin films which make up a TFT are generally produced using plasma enhanced chemical vapor deposition (PECVD). The plasma employed in PECVD may be formed remotely and then piped into a process chamber in which the thin films are deposited. In the alternative, the plasma may be formed in the process chamber in which the thin films are deposited. This latter approach is preferable, because it provides better control over the concentration and uniformity of active plasma species which are delivered to a substrate surface present in the thin film deposition process chamber.

Typically, when the plasma is formed in the deposition a process chamber, the power source used to create the plasma is an RF power source. An RF power source with matching network is connected to an RF power input area which is commonly located upon a portion of the lid to the process chamber. There is a ground for the RF power located at the susceptor/pedestal upon which rests a substrate to which a PECVD film is to be applied. This provides a plasma formation area directly over the substrate surface to which the PECVD film is to be applied. However, in such a PECVD thin film deposition system, it is also necessary to ground the fluid flow conduit structure which transports the plasma source gases, and this creates a pathway from the RF power input area to this second ground. Unless the flow of RF power to this second ground is controlled, a “parasitic” plasma can form in the fluid flow conduit structure which transports the plasma source gases.

While design variables of the apparatus may be used to reduce the stability of a parasitic plasma, thin film deposition process conditions place limitations on the apparatus design.

In addition to the parasitic plasma formation problem with respect to the plasma source gas fluid flow conduits, there is also a need to periodically clean the plasma source gas diffuser and chamber wall within the thin film deposition processing chamber. The inner surface of the processing chamber and the inner surface of the diffuser tend to build up silicon-containing hard polymeric residues which need to be removed using a fluorine-comprising plasma.

The present invention avoids parasitic plasma formation which affects the concentration of precursor plasma species at the substrate surface and which leads to the presence of the silicon-containing hard polymeric residues on plasma gas flow conduits, resulting in a source of particles which may fall onto substrates which are being processed in the PECVD thin film deposition chamber. In addition, the present invention enables more efficient cleaning for removal of the film-like residues.

### BRIEF DESCRIPTION OF THE DRAWINGS

FIG. 1 shows a schematic cross-sectional side view of one design of a PECVD thin film deposition system 100, which includes a plasma source gas supply system 103. The plasma source gas supply system 103 is used to supply gases which are subsequently converted into plasma species in a PECVD thin film deposition process chamber 105. An RF power input 118, with RF matching network 120, (present within a housing 107 shown in FIG. 1) is connected to the lid of the PECVD processing chamber at RF connection 110, and is coupled to a plasma ground which is provided by a susceptor/pedestal 124 on which the substrate 126 rests, to provide a process plasma formation region 116 above substrate 126. The spacing between the substrate 126 and the electrode/gas diffuser 122 may be adjusted by raising or lowering susceptor/pedestal 124 using lift 128. The plasma source gas, typically gases, which are the precursors for the thin film deposition, enter the PECVD processing system 100 through an inlet 104 and then travel through an RF Resistor area 109 which includes an exterior plastic housing for protection 113, a ceramic coated insulator which permits gradual voltage breakdown 114, and RF Resistor conduit section 106 having a variable surface fluid flow restrictor 108. From there, the plasma source gas flows through a process vessel entry conduit 112 to a gas diffuser 122. The gas diffuser 122 makes the plasma source gases uniformly available within the process plasma formation region 116. The plasma source gas conduit system used to transport the plasma source gases from inlet 104 to gas diffuser 122 for transfer of the plasma source gases is also grounded (not shown). FIG. 1 also shows a remote plasma generation system 102 which is used to generate a cleaning plasma for maintenance of the PECVD thin film deposition system 100.

FIG. 2 shows a graph 200 of the change in voltage in the RF Resistor conduit section 106, on axis 204 in Volts, as a function of the pressure in the RF Resistor section 106, on axis 202 in Torr. Curve 206 shows the change in Voltage across the RF Resistor section as the pressure in the RF Resistor section changes.

FIG. 3 shows a graph 300 of the maximum RF power, on axis 304 in Watts, that can be applied to a hydrogen source gas in the AKT™ 25 KA PECVD thin film processing chamber prior to plasma discharge (arcing), as a function of the pressure in the thin film processing chamber, which is shown on curves 306 (0.5 Torr), 308 (1.0 Torr), 310 (1.5 Torr), and 312 (2.0 Torr). In addition, Graph 3 shows the hydrogen gas flow in slm (standard liters per minute) on axis 302 which was used at the time the RF power was applied. Pressure in the PECVD thin film processing chamber is controlled independently from the total hydrogen gas flow.

FIG. 4 is a schematic 400 showing an enlargement of the cross-sectional side view of the RF Resistor area 109 which includes an exterior plastic housing for protection 113, a ceramic coated insulator which permits gradual voltage breakdown 114, and RF Resistor conduit section 106 having a variable surface fluid flow restrictor 108. From there, the plasma source gas flows through a process vessel entry conduit 112 to a gas diffuser 122 (not shown) This schematic 400 shows the RF Resistor conduit section 106, having an internal diameter 404, where the restriction insert 108 reduces the internal diameter to a smaller diameter 406 at the insert location.

### DETAILED DESCRIPTION OF EXEMPLARY EMBODIMENTS

As a preface to the detailed description presented below, it should be noted that, as used in this specification and the appended claims, the singular forms “a”, an and “the” include plural referents, unless the context clearly dictates otherwise.

In instances where the word “about” is used in this document, this indicates that the precision of a value is within about +10%.

It has been discovered that a parasitic plasma problem which has existed with respect to the incoming plasma source gases used in a PECVD thin film deposition system can be avoided. To avoid the formation of a parasitic plasma, an RF Resistor gas feed through conduit was designed. The design criteria was that the impedance to dissociation of a plasma source gas into a plasma in the RF Resistor conduit must be substantially greater than the impedance to dissociation of a plasma source gas into a plasma inside the PECVD thin film deposition chamber. Typically the impedance to dissociation should be at least 10% greater in the RF Resistor conduit than in the PECVD thin film deposition chamber. More typically, the impedance to dissociation should be at least 30% greater in the RF Resistor conduit. In some instances, depending on the plasma source gas and the ease of dissociation, it is advisable to use an impedance to dissociation which is about 200% to about 300% greater in the RF Resistor conduit than in the PECVD thin film deposition chamber. The RF Resistor is designed to increase the pressure in a conduit through which the plasma source gas travels, so that the amount of RF power which would have to be applied to cause formation of a stable parasitic plasma in the source gas conduit exceeds the amount of RF power required for generation of the PECVD thin film deposition plasma, as discussed above.

The increase in pressure in the conduit through which the plasma source gas travels may be obtained by inserting a restriction device in the interior of the plasma source gas conduit. The restriction device is inserted at a location along the direction of travel of the plasma source gas which is prior to entry of the source gas into a conduit which is part of the process chamber plasma generation system. The restriction device may be a variable surface restriction device. A variable surface restriction device is one where the amount of surface of the restriction device which is presented in the direction of fluid flow varies depending on the amount of flow restriction desired; or, in this instance, depending on the amount of pressure increase desired in the plasma source gas conduit leading up to the restriction device. This pressure is sometimes referred to as a “back pressure” (a pressure which builds up in the line behind the restrictive device, as gas flowing toward the restrictive device cannot travel through the conduit as rapidly).

An increase in pressure in the conduit through which a plasma source gas is flowing reduces the nominal change (decrease) in voltage which is observed when RF power is applied to the plasma source gas flowing through the conduit, which is subsequently referred to herein as an RF Resistor conduit. In an apparatus of the present invention, to protect the incoming plasma source gas from developing a parasitic plasma prior to reaching the area in which the process chamber plasma is to be generated, a specialized dual conduit area, in which pressure is controlled and electrical insulation has been provided, has been developed. The RF Resistor conduit section is present at or near the junction where the plasma source gases enter the process chamber plasma generation system.

Voltage drop across a fluid flow conduit filled with a plasma source gas has been determined to be a function of plasma impedance, which depends of particular parameters, including but not limited to: the plasma source gas or gases used to generate plasma species; the volumetric flow of plasma (plasma source gases) required to service the PECVD thin film deposition process chamber; the pressure in the fluid flow conduits through which the plasma source gases flow prior to entry into the process chamber plasma generation system; the relative sizing of various areas of the fluid flow conduits which make up the plasma source gas transfer conduits prior to entry into the process chamber plasma generation system; and the amount of power input for process chamber plasma generation.

The setting of requirements for most of the variables which affect the formation of a parasitic plasma is determined by the process requirements which must be met during the thin film deposition process. For example, for a given film, which requires a given plasma source gas, to deposit a thin film on a larger substrate surface, it is necessary to increase the amount of plasma charged to the PECVD chamber and to increase the overall amount of RF power applied. An increase in pressure drop within the RF Resistor conduit (previously described herein) has been demonstrated to be directly proportional to the increase in a substrate area to which the thin film is to be applied. This increase in substrate area demands an increase in the volumetric flow of plasma species, and in the amount of RF power applied. There are similar relationships between other variables in the film deposition process. However, there are two important variables which can be adjusted to reduce parasitic plasma formation without affecting the process being carried out in the film deposition processing chamber. These variables are the relative sizing of various sections of the fluid flow conduits leading up to the entry of the plasma source gases into the process chamber plasma generation system. An example of such a pressure would be the pressure in the RF Resistor conduit which was described above.

The pressure in the RF Resistor conduit section of the plasma source gas fluid flow conduits can be increased by placing a restrictive device in the area where plasma source gases exit from the RF Resistor fluid flow conduit. This action has been shown to significantly reduce voltage drop across the RF Resistor, and to reduce the formation of a stable parasitic plasma from the RF Resistor conduit section back toward the incoming supply of plasma source gases. However, during the cleaning of the plasma source gas supply conduits, the plasma source gas diffuser, and the process chamber plasma generation area, the higher pressure in the RF Resistor fluid flow conduit reduces the effectiveness of the plasma cleaning species introduced from a remote plasma source to remove film-like residues which build up over time. The plasma cleaning species tend to lose energy under the higher pressure conditions, and tend to recombine back into their neutral plasma source gas condition. As a result, the time required to clean process chamber plasma generation apparatus is increased.

The cleaning time can be reduced by using a variable restriction device, rather than a fixed restriction device, at or adjacent to the point of entry of the plasma source gases into the process chamber plasma generation system. Typically this is at the exit from the RF Resistor conduit section. The variable restriction device needs to be one which does not become a source of particulates which enter the thin film deposition process chamber and reduce the yield of the product produced in the chamber. Many of the plasma source gases and high energy species generated from these source gases are highly corrosive. The RF Resistor conduit section which was previously described was fabricated from alumina ceramic, Al₂O₃. Other materials which may be used include Zr₂O₃ and graphite, by way of example and not by way of limitation. The material from which the RF Resistor conduit section is formed must be mechanically adequate to act as a fluid flow conduit at the vacuum conditions applied, and the material must be capable of withstanding plasma source gases comprising hydrogen, silicon (in the form of silane (SiH₄) for example and not by way of limitation), and even fluorine molecules or radicals (which is typically used during the cleaning process). This same ceramic can be used to fabricate a variable restrictor which is present where the plasma source gases exit from the RF Resistor conduit and flow into the into the process chamber plasma generation system.

One example of such a variable restrictor is a “butterfly valve” which is simply a disk which pivots around an axis within the exit area of the RF Resistor conduit. Such a ceramic disk presents only a thin sliver in the form of the edge of the disk at minimal restriction, when the pressure needs to be low, particularly during the cleaning process. This edge profile provides minimal exposure to the corrosive fluorine-containing species used for cleaning. During thin film generation and film-forming plasma generation, when the pressure in the RF Resistor conduit needs to be high, to reduce voltage drop across the RF Resistor, a larger surface area of the ceramic butterfly valve disk is exposed. However, the ceramic is generally resistive to corrosion by gases such as nitrogen, hydrogen, SiH₄, Si₂H₆, PH₃, B₂H₆, and N₂O, by way of example and not by way of limitation. In addition, the ceramic may be polished to have a smooth surface which tends to generate fewer particles, if the application demands this.

While a disk mounted so that it rotates about a pivot line within an internal diameter of a fluid flow conduit is an excellent example of a minimum profile exposure (in the direction of plasma source gas flow) variable restriction device which can be fabricated to reduce particulate generation, one of skill in the art will recognize that there are other variable restriction device designs, such as gate valves, which are also advantageous, and it is not the intent of the inventor that the variable restriction device be limited to a butterfly valve.

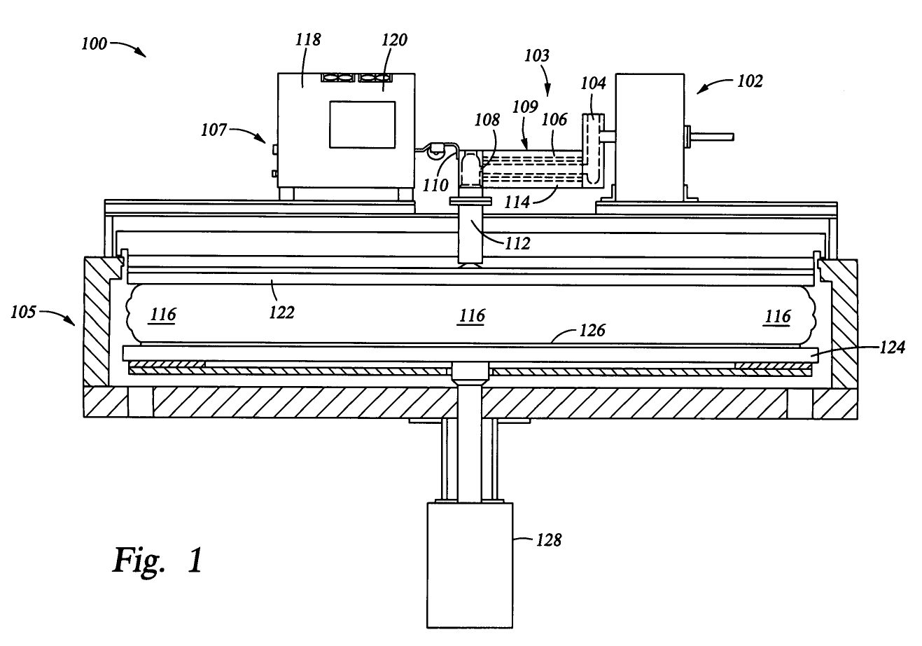

FIG. 1 shows a schematic cross-sectional side view of one design of a PECVD thin film deposition system 100, which includes a plasma source gas supply system 103. The plasma source gas supply system 103 is used to supply gases which are subsequently converted into plasma species in a PECVD thin film deposition process chamber 105. An RF power input 118, with RF matching network 120 are present within housing 107 shown in FIG. 1. The RF power is transferred into the thin film deposition system 100 through connection 110, traveling to plasma formation region 116 via gas diffuser 122 which is designed to perform as an upper electrode for the plasma formation region 116. A bottom electrode for the plasma formation region 116 is susceptor/pedestal 124 on which substrate 126 rests. The susceptor/pedestal 124 provides a ground for the plasma formation region 116. The spacing between substrate 126 and the electrode/gas diffuser 112 may be adjusted by raising or lowering susceptor/pedestal 124 using lift 128. The plasma source gas, typically gases, which are the precursors for the thin film deposition, enter the PECVD processing system 100 through an inlet 104 and travel through RF Resistor conduit section 106, typically having a variable surface fluid flow restrictor 108, and through a process vessel entry conduit 112 to gas diffuser 122. The RF Resistor conduit 106 fabricated from a ceramic material, is surrounded by a second ceramic conduit section 114 to form RF Resistor area 109.

The plasma source gas system 103 used to transport the plasma source gases from inlet 104 to gas diffuser 122 for transfer of the plasma source gases is also grounded (not specifically illustrated) by connection to the lid of PECVD thin film processing chamber 105. This subjects the plasma source gas present in gas system 103 to possible formation of a parasitic plasma due to power available from RF connection 110. The present invention avoids the formation of such a parasitic plasma.

The cleaning device 102, shown in FIG. 1, is used for the removal of thin film residues which form on the inner surfaces of PECVD thin film deposition process chamber 105 and on the surfaces of electrode/gas diffuser 122. Cleaning device 102 includes the apparatus (not shown) necessary to form a remote plasma, which remote plasma, typically containing reactive fluorine species to assist in the removal of silicon-containing hard polymer residue build up, travels through plasma source gas entry conduit 104, RF Resistor conduit 106, variable surface fluid flow restrictor 108, and plasma source gas exit conduit 112 into electrode/gas diffuser 112 and into the interior of PECVD thin film deposition process chamber 105.

The voltage drop across a plasma source gas conduit section has been determined to be directly related to the formation of parasitic plasma in such a conduit section. The larger the voltage drop, the greater the possibility of formation of a parasitic plasma.

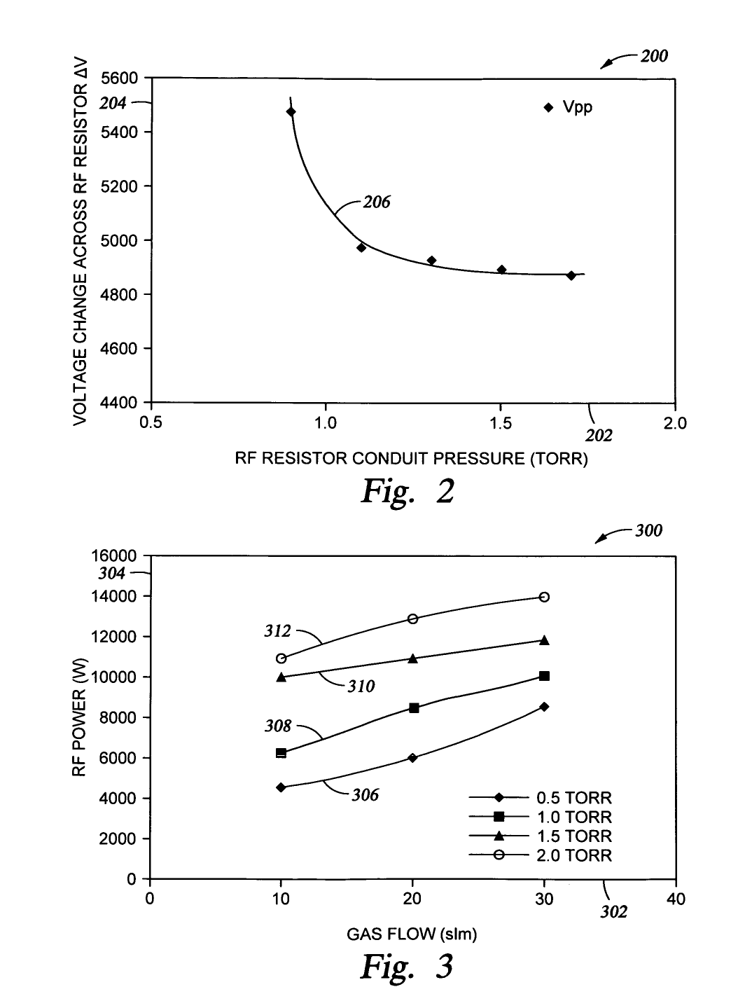

FIG. 2 shows a graph 200 of the change in voltage drop, ΔVon axis 204, across the RF Resistor section 106, as a function of the pressure, on axis 202, in Torr, within the RF Resistor section 106. As illustrated in curve 206, the change in voltage, ΔV, across the RF Resistor conduit decreases slightly, from about 5000 volts to about 4850 volts. However, when the pressure drops below about 1 Torr, there is a sudden, unexpected increase in the change in voltage across the RF Resistor, and at about 0.9 Torr, the change in voltage has increased to about 5500 Volts, indicating that the RF Resistor impedance of power transfer toward ground has decreased drastically. This drastic decrease in impedance provided by the RF Resistor conduit section of the plasma source gas supply increases the possibility that a parasitic plasma may be formed in the RF Resistor conduit section 106 into which plasma source gases are flowing.

The data provided in FIG. 2 is for an AKT™ processing chamber plasma generation system and PECVD processing chamber system designated 25 KA. This 25 KA system includes a film deposition process chamber volume adequate to process substrates having a surface area of 2,775,000 mm² (27,750 cm²), where the RF Resistor ceramic conduit section for gas flow feedthrough has an internal diameter of about 32 mm (1.25 inches) and a length of about 381 mm (15 inches). Prior to the present invention, there was a problem with parasitic plasma formation in the plasma source gas prior to the source gas reaching the plasma generation conduit area of the processing chamber plasma generation system.

FIG. 3 shows a graph 300 of the maximum RF power, on axis 304 in Watts, that can be applied to a hydrogen source gas in the AKT™ 25 KA PECVD thin film processing chamber prior to plasma discharge (arcing), as a function of the pressure in the thin film processing chamber, which is shown on curves 306 through 312. Curve 306 is when the processing chamber pressure is 0.5 Torr; Curve 308 is when the processing chamber pressure is 1.0 Torr, Curve 310 is when the processing chamber pressure is 1.5 Torr, and Curve 312 is when the processing chamber pressure is 2.0 Torr. In addition, Graph 3 shows the gas flow in slm (standard liters per minute) on axis 302 which was used at the time the RF power was applied. In addition, Graph 3 shows the hydrogen gas flow in slm (standard liters per minute) on axis 302 which was used at the time the RF power was applied. Pressure in the PECVD thin film processing chamber is controlled independently from the total hydrogen gas flow, as pressure in the thin film processing chamber is monitored and a control valve is used to control the exit of plasma source gases and species from the process chamber, so that the desired PECVD thin film deposition process chamber pressure is maintained.

Hydrogen plasma source gas was used in the experiments because hydrogen is the most easily dissociated plasma source gas of the gases used during thin film deposition on a substrate. This is true with respect to both the RF Resistor gas feedthrough and in the PECVD thin film deposition chamber. If there is no parasitic plasma in the RF Resistor gas feedthrough conduit when hydrogen is flowing through the conduit, there should be no parasitic plasma for thin film deposition processes which use other plasma source gases, such as SiH₄ in combination with H₂.

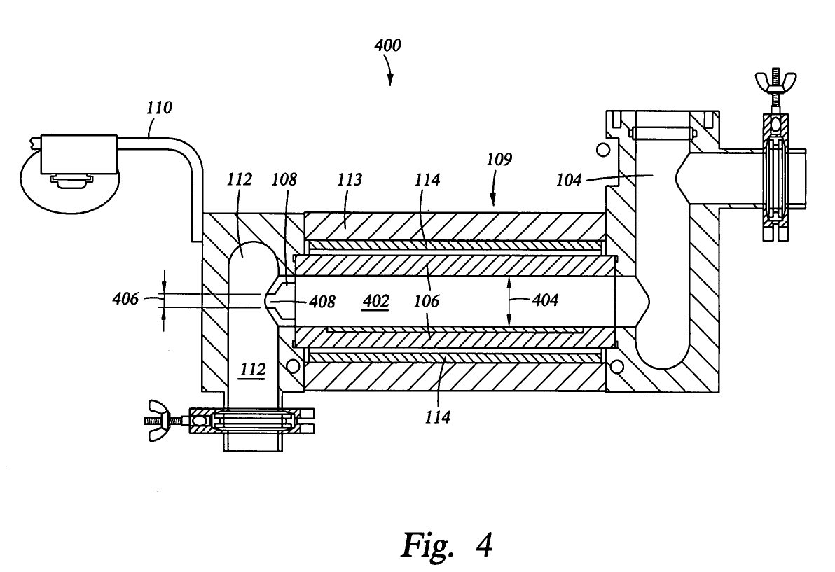

FIG. 4 is a schematic 400 of a cross-sectional side view of an RF Resistor area 109 and particularly of RF conduit section 106 of the kind shown in FIG. 1. This schematic 400 shows the plasma source gas entry 104, where plasma source gases enter the system. The plasma source gases then flow to an RF Resistor area 109 which includes an exterior plastic housing for protection 107, a ceramic coated insulator which permits gradual voltage breakdown 114, and RF Resistor conduit section 106 having a variable surface fluid flow restrictor 108. The resistance of the ceramic coated insulator 114 is typically greater than about 100 kOhm. After passing through RF Resistor area 109, the plasma source gases flow into a process vessel entry conduit 112, and from there to a gas diffuser 122. The plasma source gas inlet 104 is grounded and the process vessel entry conduit 112 is an RF hot section. As a result, the RF hot (112) and RF to ground (104) are separated by the RF Resistor.

RF Resistor conduit section 106 provides an interior ceramic conduit 402 having an internal diameter 404, which is reduced at insert 108 to provide a smaller diameter 406 at the exit 408 from conduit 402. The restriction 108 reduces the diameter at gas exit 408 as a means of increasing the pressure in the RF Resistor conduit section 106. This increase in pressure increases the RF Resistor conduit section 106 impedance to the transfer of RF power across the RF Resistor conduit section 106, reducing the probability of plasma discharge and the formation of a parasitic plasma in the plasma source gas prior to entry into the process chamber plasma formation area (not shown in FIG. 4).

Various sizes of restrictors were used in the RF Resistor conduit section for the 25 KA PECVD film deposition processing system described above, in an attempt to reduce the parasitic plasma formation in the plasma source gas flow conduits leading into the plasma formation conduit area of the processing chamber plasma generation system. A restrictor having an internal diameter of 20 mm (0.79 inch) did not provide a suitable “back pressure” within the RF Resistor conduit section 106 shown in FIGS. 1 and 3, for certain process conditions. For example, when the hydrogen flow rate was about 20 slm and the process chamber pressure was controlled at 1.0 Torr pressure, an RF Resistor having an internal diameter of 14 mm (0.55 inch) did provide a satisfactory pressure of 10 Torr within the RF Resistor conduit section 106.

One of skill in the art upon reading the disclosure herein will be able to size an RF Resistor conduit section so that the desired pressure in the RF Resistor conduit section 106 can be obtained for PECVD thin film processing systems designed for other substrate sizes. For example, an AKT™ processing system which can be used to deposit thin films on substrates up to 13,750 cm² in size, the AKT™ 15K processing system, which makes use of an RF Resistor conduit section 106 which has a length of about 220 mm (8.67 inch) and a diameter of about 19 mm (0.75 inch) provides a pressure in the RF Resistor conduit section 401 of about 10 Torr when the nominal gas flow of hydrogen is about 10.0 slm. An AKT™ processing system which can be used to deposit thin films on substrates up to 43,875 cm² in size, the AKT™ 40K processing system, which makes use of an RF Resistor conduit section 106 which has a length of about 381 mm (15 inches) and a diameter of about 25.3 mm (1.0 inches) provides a pressure in the RF Resistor conduit section 401 of about 7 Torr when the nominal gas flow of hydrogen is about 40.0 slm. Both of these RF Resistor conduit section designs provide a satisfactory pressure in the RF Resistor conduit section to avoid formation of a stable parasitic plasma.

However, as previously mentioned, when the pressure in the RF Resistor conduit is adequate to prevent parasitic plasma formation, it also prevents efficient cleaning of the plasma source gas diffuser, and substrate processing chamber.

As discussed above, while the creation of a higher pressure in the plasma source gas conduits leading up to the processing chamber plasma generation conduit is helpful in terms of avoiding formation of a parasitic plasma in the plasma source gas conduits, such a pressure increase is not helpful when silicon-containing hard polymeric residue needs to be cleaned off internal surfaces of the PECVD thin film deposition chamber. This residue is removed by a cleaning process which makes use of a fluorine-containing plasma which is remotely generated and fed into the conduits used for transfer of the plasma source gases. Due to the higher pressure in the RF Resistor fluid flow conduit, and indirectly other plasma source gas flow conduits leading into the RF Resistor conduit, the fluorine-comprising species present in the remotely generated cleaning plasma tend to drop to a lower energy level, some even returning to their neutral initial state, reducing the effectiveness of the plasma cleaning process. Experiments were performed in the AKT™ 25 KA PECVD thin film deposition system, where the thin film deposition plasma is formed in the film deposition process chamber. Various restrictors were used at the exit point of plasma source gases from the RF Resistor conduit. The experiments showed that when the internal diameter of the RF Resistor was reduced to about 12.7 mm (0.5 inches) in the area of exit, the cleaning time for removal of silicon-containing hard polymer residue form the thin film deposition processing chamber increased from about 106 seconds to about 124 seconds.

To provide protection from formation of parasitic plasma in the plasma source gas fluid flow conduits, while permitting a rapid cleaning time for the processing chamber plasma generation system, the restrictor placed at the exit to the RF Resistor fluid flow conduit needs to be variable so that restriction can be adequate during the thin film deposition process and minimized during the cleaning process which follows. There are many possible valve designs which permit varying degrees of restriction (varying degrees of opening size for fluid flow through the valve). However, in the present instance, the material on the valve surface must resist corrosive, fluorine-containing species, and cannot be a source for particulate generation, which particles may find a final resting place on the surface of a substrate on which the PECVD thin films are being deposited. This eliminates a large number of valve materials of construction and valve designs where surfaces frictionally slide over other surfaces.

The fluid flow conduit used for the RF Resistor conduit is typically fabricated from an aluminum oxide (Al₂O₃) ceramic material. Other similar ceramic materials which are good electrical insulators and which are resistant to corrosive gases may be used. A ceramic material of this kind has been shown to be resistant to corrosive fluorine-containing plasmas and is known to produce a minimal number of particulates when contacted by typical plasma source gases.

One example of a variable restrictor design which could be used in the present application is a “butterfly valve”, where the valve comprises a disk which is mounted within an internal diameter of a conduit so that it can rotate within the conduit about a pivotal axis. The angle of rotation relative to the direction of fluid flow determines the amount of opening/restriction across the conduit opening. The ceramic disk can be spaced a nominal clearance distance from the internal diameter of the conduit, so that there is no contact of the rotating disk with the internal diameter of the conduit. When the pressure is to be increased in the RF Resistor conduit section, the disk can be rotated to block off as much of the conduit opening as is beneficial. One skilled in the art can easily calculate this based on the sizing of the fluid flow conduits and gas flow rates. When the cleaning operation is to be performed for removal of silicon-containing hard polymer, the ceramic disk can be rotated to permit maximum conduit opening. In this instance it is only the edge of the disk which comes in contact with the fluorine-containing plasma species used for cleaning. As a result, the possibility for particulate generation is reduced. There are other examples of variable restrictors, such as a gate valve, which may be designed for this application. Those of skill in the art will be able to envision a number of possibilities.

While the invention has been described in detail above with reference to several embodiments, these embodiments are not intended to be limiting with respect to the invention, as one of skill in the art in this technological field will recognize that various modifications within the scope and spirit of the invention may be made, to expand the concepts and the materials which may be used to correspond with the subject matter claimed below.

We claim:

1. A method of avoiding the formation of a parasitic plasma in a plasma source gas supply conduit leading to a thin film PECVD deposition processing chamber, comprising: forming an RF resistor conduit within said plasma source gas supply conduit, which RF resistor conduit permits gradual voltage breakdown of RF power traveling through said plasma source gas supply conduit, and placing a variable surface restrictive device within said RF resistor conduit or between said RF resistor conduit and said PECVD processing chamber, wherein said variable surface restrictive device is used to increase a pressure in said plasma source gas supply conduit to a pressure which exceeds a minimum pressure of greater than at least 0.9 Torr, which minimum pressure is necessary to avoid formation of a parasitic plasma in said plasma source gas supply conduit at an RF power required to generate a processing plasma in said thin film PECVD processing chamber.

2. (canceled)

3. (canceled)

4. A method in accordance with claim 1, wherein said variable surface restriction device comprises ceramic on an exterior surface, whereby corrosion of said variable surface restriction device is reduced.

5. A method in accordance with claim 1, wherein an exterior surface of said variable surface restriction device comprises a material selected from the group consisting of Al₂O₃, Zr₂O₃ and graphite.

6. A method in accordance with claim 4 or claim 5, wherein a ceramic-comprising disk is inserted in said plasma source gas supply conduit in a manner such that said ceramic-comprising disk operates as a variable surface restriction device.

7.-14. (canceled)

15. A method in accordance with claim 6, wherein said ceramic-comprising disk is installed as a component of a butterfly valve.

16. A method in accordance with claim 1, wherein said minimum pressure is such that the impedance to dissociation of a plasma source gas to form a plasma inside said plasma source gas supply conduit is at least 10% greater than the impedance to dissociation of said plasma source gas in said PECVD thin film deposition chamber.

17. A method in accordance with claim 16, wherein said impedance to dissociation of a plasma source gas within said plasma source gas supply conduit ranges from 10% greater to 300% greater than the impedance to dissociation of said plasma source gas in said PECVD thin film deposition chamber.

18. A method in accordance with claim 1, wherein said minimum pressure in said plasma source gas supply conduit is such that the impedance to dissociation of a plasma source gas to form a plasma inside said plasma source gas supply conduit ranges from about 10% greater to about 300% greater than the impedance to dissociation of said plasma source gas in said PECVD thin film deposition chamber.

19. A method in accordance with claim 18, wherein said minimum pressure is such that the impedance to dissociation of a plasma source gas to form a plasma inside said plasma source gas supply conduit ranges from about 200% greater to about 300% greater than the impedance to dissociation of said plasma source gas in said PECVD thin film deposition chamber.
